(19) United States
(12) Patent Application Publication
(10) Pub. No.: US 2023/0408697 A1
(43) Pub. Date: Dec. 21, 2023

(54) OPTOELECTRONIC MODULE COMPRISING AN INTERLOCK FEATURE

(71) Applicant: AMSN SENSORS SINGAPORE PTE. LTD, Singapore (SG)

(72) Inventors: Javier Miguel Sánchez, Zurich (CH); Andrea Di Chele, Zurich (CH)

(21) Appl. No.: 18/250,672

(22) PCT Filed: Nov. 26, 2021
(86) PCT No.: PCT/SG2021/050731

§ 371 Date: Apr. 26, 2023

(30) Foreign Application Priority Data
Dec. 15, 2020 (GB) 2019769.5

(51) Int. Cl. G01S 17/89; G01S 7/481

(52) U.S. Cl. CPC G01S 17/89; G01S 7/4813; G01S 7/4814

(57) ABSTRACT

An optoelectronic module comprising: a radiation-emitting device; a housing comprising a wall or walls laterally surrounding the radiation-emitting device; two or more terminals disposed on a surface of the wall or walls; a transparent substrate abutting the housing, the transparent substrate comprising an interlock feature; a control unit coupled to the two or more terminals, wherein the control unit is configured to: supply an electrical current though the interlock feature; monitor an electrical parameter associated with the interlock feature; wherein the terminals are arranged such that: when the transparent substrate is in a first orientation about an optical axis of the radiation-emitting device, the interlock feature is coupled to at least two of the two or more terminals and the optoelectronic module is operable to provide a field of illumination in a first illumination orientation; and when the transparent substrate is in a second orientation about the optical axis of the radiation-emitting device, the interlock feature is coupled to at least two of the two or more terminals and the optoelectronic module is operable to provide a field of illumination in a second illumination orientation different from the first illumination orientation.

### TECHNICAL FIELD

This disclosure relates to optoelectronic modules having an interlock feature.

### BACKGROUND

Mobile communications devices, such as smart phones, tablets, laptop computers, and other portable computing devices, can include technologies to record three-dimensional images, sense motion and/or gestures. Digital recording methods use various types of miniature optoelectronic modules, which interact with cameras to record dynamical events in three-dimensional regions. These optoelectronic modules can be of various forms and deliver different types of functions. Some illuminate a wide area with very short pulses for Light Detection and Ranging (LIDAR) type measurements recording time of flight information. Others are pulsed or continuous wave (CW), and project structured light patterns onto a scene. A digital camera records an image of the structured light pattern, and software algorithms are used to determine three-dimensional scene information from modifications in the patterned image.

Optoelectronic modules may include one or more devices for emission of visible and/or invisible radiation, such as a light-emitting diode, or a laser, such as a vertical cavity surface emitting laser (VCSEL) device. Various optical components (e.g., an optical diffuser and/or a microlens array) can be placed in the beam path to modify the beam properties for the specific application.

The radiation-emitting devices and/or the optical component(s) may be arranged such that a particular orientation of the optoelectronic module determines a field of illumination of the modified beam, e.g. portrait or landscape, configured to match a field of view of the camera.

The optical output power of a bare radiation-emitting device can, in some cases, be so high that it may cause damage to a person's eye or skin in the event that the quality of the optical component is compromised. Thus, it is important to ensure that high power radiation-emitting devices meet laser safety regulations when operated in a mobile communications device. For example, the optoelectronic module may be part of an assembly that, under normal operating conditions, maintains eye-safe operation by preventing a person from getting too close to the optoelectronic module. However, in some cases, damage (e.g., cracks) to the optical component(s) that modifies the output beam for safe operation, or the presence of moisture or chemical contamination on the optical component(s), may result in safety hazards. Likewise, if the optical component(s) were to fall off or be removed, safety could be compromised.

### SUMMARY

The present disclosure relates to optoelectronic modules having an interlock feature for detection of damage to the optical structure and/or the optoelectronic module.

According to a first aspect of the present disclosure, there is provided an optoelectronic module comprising:
a radiation-emitting device;
a housing comprising a wall or walls laterally surrounding the radiation-emitting device;
two or more terminals disposed on a surface of the wall or walls;
a transparent substrate abutting the housing, the transparent substrate comprising an interlock feature;
a control unit coupled to the two or more terminals, wherein the control unit is configured to:
   supply an electrical current though the interlock feature;
   monitor an electrical parameter associated with the interlock feature;
wherein the terminals are arranged such that:
when the transparent substrate is in a first orientation about an optical axis of the radiation-emitting device, the interlock feature is coupled to at least two of the two or more terminals and the optoelectronic module is operable to provide a field of illumination in a first illumination orientation; and
when the transparent substrate is in a second orientation about the optical axis of the radiation-emitting device, the interlock feature is coupled to at least two of the two or more terminals and the optoelectronic module is operable to provide a field of illumination in a second illumination orientation different from the first illumination orientation.

Embodiments of the present disclosure advantageously enable damage to the housing and/or the transparent substrate to be detected through detection of changes in the electrical parameter associated with the interlock feature. For example, in embodiments of the present disclosure, an interruption in conduction of the electrical current through the interlock feature could be detected. This may indicate, for example, damage to and/or removal of the transparent substrate.

Embodiments of the present disclosure further advantageously enable an optoelectronic module comprising an interlock feature to be configurable to provide a field of illumination in two or more different orientations (e.g. portrait and landscape) by adjusting only the orientation of the transparent substrate, where such different orientations would otherwise necessitate manufacturing of different optoelectronic modules for each orientation according to a configuration of a host device, such as a mobile communications device.

In some embodiments, the two or more terminals comprise a first terminal and a second terminal, wherein in the first orientation a first contact pad of the interlock feature is coupled to the first terminal and a second contact pad of the interlock feature is coupled to the second terminal; and wherein in the second orientation the first contact pad of the interlock feature is coupled to the second terminal and the second contact pad of the interlock feature is coupled to the first terminal.

Optoelectronic modules comprising only two terminals may be advantageously simplified over optoelectronic modules comprising additional redundant terminals, which may enable a simplified process for manufacturing the modules.

In some embodiments, where the optoelectronic module comprises a plurality of walls, the first terminal is disposed on a surface of a first wall of the housing, and the second terminal is disposed on a surface of one or more further walls of the housing.

In some embodiments, where the optoelectronic module comprises one wall, the first terminal is disposed on a first portion of the surface of the wall, and the second terminal is disposed on a second portion of the surface of the wall.

In some embodiments, the two or more terminals comprise a first terminal, a second terminal, a third terminal, and a fourth terminal, wherein in the first orientation a first contact pad of the interlock feature is coupled to the first terminal, a second contact pad of the interlock feature is coupled to the second terminal, a third contact pad of the interlock feature is coupled to the third terminal, and a fourth contact pad of the interlock feature is coupled to the fourth terminal; and wherein in the second orientation the first contact pad of the interlock feature is coupled to the second terminal, the second contact pad of the interlock feature is coupled to the third terminal, the third contact pad of the interlock feature is coupled to the fourth terminal, and the fourth contact pad of the interlock feature is coupled to the first terminal.

Embodiments comprising a first, second, third and fourth terminal enable four-point probe sensing of the electrical parameter associated with the interlock feature. This can advantageously enable improved measurement accuracy, since the effect of contact resistance between the interlock feature and the terminals is eliminated in four-point probe measurements. For example, where the electrical parameter is a resistance, much smaller resistances can be measured than in two-point probe resistance measurements. This enables fabrication of smaller optoelectronic modules, as smaller modules require smaller interlock features, which would produce smaller resistances, which may be of a similar magnitude to the contact resistance. Elimination of the contact resistance from the measurement can also advantageously lead to improved uniformity between mass-produced optoelectronic modules, as variation in contact resistance can occur between modules.

In some embodiments, in the first orientation the control unit is configured to supply the electrical current to the interlock feature between the first terminal and the second terminal and to monitor the electrical parameter between the third terminal and the fourth terminal; and in the second orientation the control unit is configured to supply the electrical current to the interlock feature between the third terminal and the fourth terminal and to monitor the electrical parameter between the first terminal and the second terminal.

Embodiments in which the control unit is configured to supply the current to the interlock feature, and to monitor the electrical parameter, between different pairs of terminals according to the orientation of the transparent substrate enable four-point probe measurements where the interlock feature is optimised for a particular arrangement of terminals for current supply and monitoring.

In some embodiments, the terminals, the interlock feature, and the control unit are configured as a Wheatstone bridge.

A Wheatstone bridge configuration advantageously enables the electrical parameter to be monitored with a high precision, further enabling the manufacture of smaller optoelectronic modules.

In some embodiments, the two or more terminals comprise a first terminal, a second terminal, a third terminal, a fourth terminal, a fifth terminal, and a sixth terminal, wherein in the first orientation a first contact pad of the interlock feature is coupled to the second terminal, a second contact pad of the interlock feature is coupled to the third terminal, a third contact pad of the interlock feature is coupled to the fourth terminal, and a fourth contact pad of the interlock feature is coupled to the fifth terminal; and wherein in the second orientation the first contact pad of the interlock feature is coupled to the fourth terminal, the second contact pad of the interlock feature is coupled to the fifth terminal, the third contact pad of the interlock feature is coupled to the sixth terminal, and the fourth contact pad of the interlock feature is coupled to the first terminal; and wherein in the first orientation the control unit is configured to supply the electrical current to the interlock feature between the second terminal and the third terminal and to monitor the electrical parameter between the fourth terminal and the fifth terminal; and wherein in the second orientation the control unit is configured to supply the electrical current to the interlock feature between the fourth terminal and the fifth terminal and to monitor the electrical parameter between the sixth terminal and the first terminal.

Embodiments comprising six terminals also enable four-point probe monitoring of the electrical parameter in both the first and second orientations where the interlock feature is optimised for a particular configuration of terminals for current supply and monitoring.

In some embodiments, the interlock feature comprises a first track and a second track, wherein the first track is longer than the second track and the electrical current is provided along the first longer track.

Providing electrical current along the long track may be optimal for four-point probe monitoring of the electrical parameter.

In some embodiments, the optoelectronic module further comprises an optical element coupled to the transparent substrate, wherein the optical element is configured to provide the field of illumination. The optical element may comprise one or more lenses. For example, the optical element may comprise a microlens array.

In some embodiments, the electrical parameter comprises one or more of a voltage; a current; a capacitance; and/or a resistance.

In some embodiments, the radiation-emitting device comprises at least one VCSEL.

In some embodiments, the control unit is further configured to initiate a safety action if the electrical parameter falls outside of a pre-determined acceptable range, wherein initiating the safety action comprises transmitting a control signal to the radiation-emitting device.

Transmitting a control signal to the radiation-emitting device may, for example, enable the electronic module to switch off the radiation-emitting device, or to reduce the power of the radiation-emitting device to a safe level, automatically and immediately after the safety of the optoelectronic module is detected to have been compromised.

In some embodiments, the interlock feature is disposed on a surface of the transparent substrate.

In some embodiments, the transparent substrate is made of glass.

In some embodiments, the terminals are disposed on an upper surface of the wall or walls.

In some embodiments, the terminals are disposed on a side surface of the wall or walls.

In some embodiments, the optoelectronic module is configured as one or more of: an infrared illuminator; a time-of-flight sensor; and/or a proximity sensor.

According to a second aspect of the present disclosure, there is provided a mobile communications device comprising the optoelectronic module according to the first aspect. The mobile communications device may be, for example, a smartphone, a tablet device, a laptop computer, or a camera.

### BRIEF DESCRIPTION OF THE PREFERRED EMBODIMENTS

Some embodiments of the disclosure will now be described by way of example only and with reference to the accompanying figures, in which:

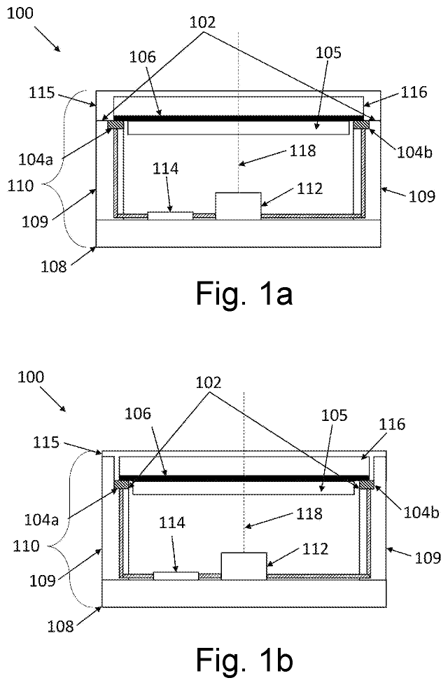

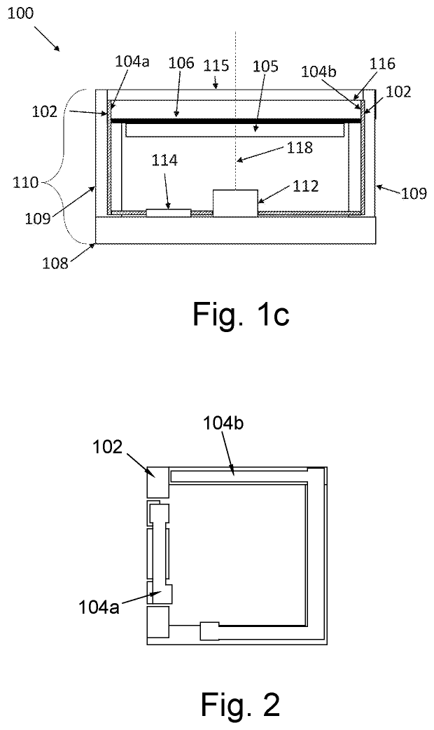

FIGS. 1a to 1c illustrate various examples of optoelectronic modules according to the present disclosure;

FIG. 2 illustrates a plan view of an example of an optoelectronic module according to the present disclosure;

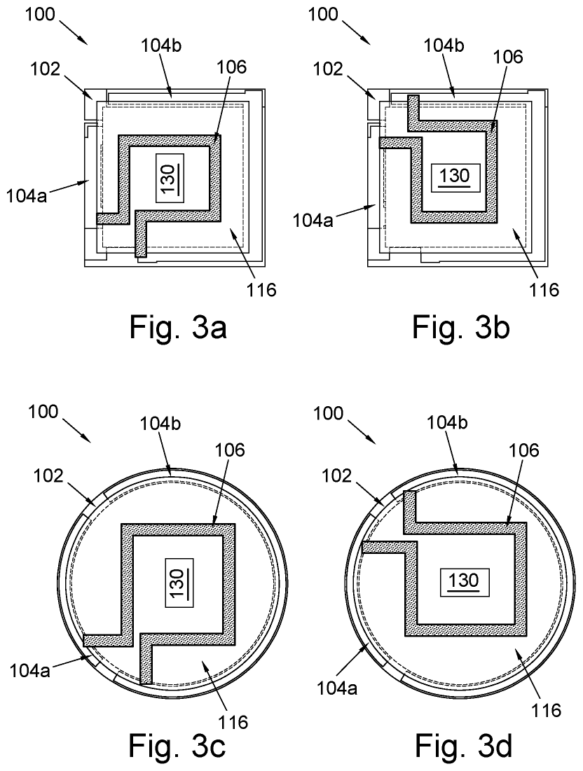

FIGS. 3a, 3b, 3c, and 3d illustrate examples of a transparent substrate comprising an interlock feature and mounted to a housing of an optoelectronic module in first and second orientations, wherein the housing comprises three terminals and the interlock feature comprises two contact pads, according to the present disclosure;

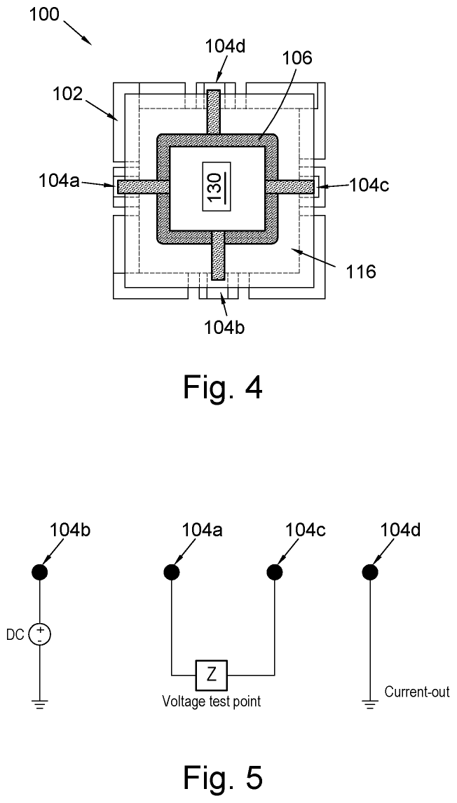

FIG. 4 illustrates an example of a transparent substrate comprising an interlock feature and mounted to a housing of an optoelectronic module, wherein the housing comprises four terminals and the interlock feature comprises four contact pads, according to the present disclosure;

FIG. 5 illustrates an example of a circuit diagram showing a configuration of four terminals;

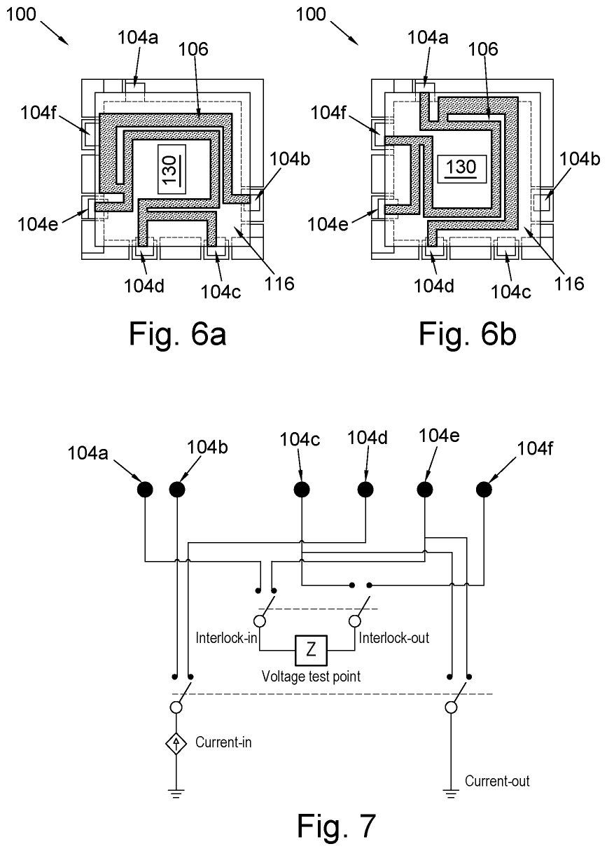

FIGS. 6a and 6b illustrate an example of a transparent substrate comprising an interlock feature and mounted to a housing of an optoelectronic module, wherein the housing comprises six terminals and the interlock feature comprises four contact pads, according to the present disclosure;

FIG. 7 illustrates an example of a circuit diagram comprising switches for reconfiguring six terminals either for supplying a current to an interlock feature, for monitoring an electrical parameter associated with the interlock feature, or as inactive terminals, according to the present disclosure; and

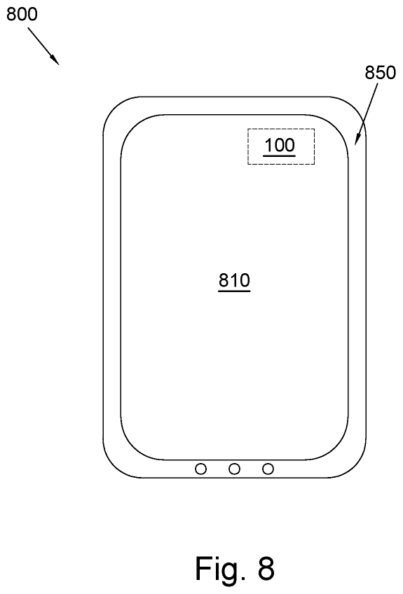

FIG. 8 illustrates a mobile communications device according to the present disclosure.

### DETAILED DESCRIPTION OF THE PREFERRED EMBODIMENTS

Embodiments will now be described by way of example only with reference to the accompanying figures.

FIGS. 1a, 1b, and 1c illustrate examples of an optoelectronic module 100 according to embodiments of the present disclosure.

As illustrated in FIG. 1a, an optoelectronic module 100 comprises a radiation-emitting device 112 and a housing 110. The housing 110 comprises a wall or walls 109 laterally surrounding the radiation-emitting device. In an example, the housing 110 may have a cuboidal shape, wherein the housing 110 comprises four walls 109. In another example, the housing 110 may have a cylindrical shape, wherein the housing 110 comprises one cylindrical wall 109. However, the housing 110 may have any other shape and may comprise any number of walls 109. The radiation-emitting device 112 may comprise one or more light emitting diodes (LEDs), lasers, or other devices. In some embodiments, the radiation-emitting device 112 comprises one or more vertical-cavity surface-emitting lasers (VCSELs). The radiation-emitting device 112 may be configured to emit visible light and/or invisible radiation, such as infrared or near-infrared radiation.

The housing 110 may further comprise a base 108 on which the radiation-emitting device 112 and the wall or walls 109 are disposed. In some examples, the base 108 may comprise a printed circuit board.

The optoelectronic module 100 further comprises two or more terminals 104 disposed on a surface 102 of the wall or walls 109. In some examples, the surface 102 on which the two or more terminals 104 are disposed is an upper surface of the wall or walls 109. The upper surface may be e.g. a topmost surface, as illustrated in FIG. 1a, or an upper surface of a recess in the housing 110, as illustrated in FIG. 1b. Two terminals 104a, 104b disposed on an upper surface 102 are shown in plan view in FIG. 2. The other components of the optoelectronic module 100 are omitted from FIG. 2 for clarity. In other examples, such as illustrated in FIG. 1c, the surface 102 is a side surface of the wall or walls 109.

The optoelectronic module 100 further comprises a transparent substrate 116 abutting the housing 110, wherein the transparent substrate 116 is transmissive of radiation having a wavelength or wavelengths emitted by the radiation-emitting device 112. The transparent substrate 116 preferably comprises glass. However, other materials are suitable, for example plastic. In some embodiments, the substrate layer 110 can comprise SiO₂ or “display” glass, such as Schott D263T-ECO or Borofloat 33, Dow-Corning Eagle 2000. The transparent substrate 116 comprises an interlock feature 106. The interlock feature 106 may be disposed on a surface of the transparent substrate 116, as illustrated in FIG. 1a. In an alternative example, the interlock feature 106 may be at least partially encapsulated inside the transparent substrate 116. The interlock feature 106 may comprise, for example, indium tin oxide, chromium oxide, or any other suitable electrically conductive material.

The terminals 104, the transparent substrate 116, and the interlock feature 106 are configured such that, when the transparent substrate 116 is abutting the housing 110, the interlock feature 106 is coupled to at least two of the terminals 104. In examples where the interlock feature 106 is encapsulated inside the transparent substrate 116, the interlock feature 106 may couple to the terminals 104 via one or more openings in the transparent substrate 116.

The optoelectronic module 100 may further comprise a protective layer 115 disposed over the transparent substrate 116 and the surface 102 of wall or walls 109. The protective layer may encapsulate the transparent substrate 116, the surface 102 of wall or walls 109, and/or the terminals 104. The protective layer is transmissive of radiation having a wavelength or wavelengths emitted by the radiation-emitting device 112. The protective layer 115 may comprise a glass (e.g. SiO₂).

The terminals 104 are coupled to a control unit 114. The control unit 114 may comprise an application-specific integrated circuit (ASIC). In the examples illustrated in FIGS. 1a-c, the control unit 114 is illustrated as being disposed on the base 108 and enclosed by the housing 110. However, the control unit 114 may alternatively be situated outside of the optoelectronic module 100 entirely. The control unit 114 is configured to supply an electrical current to the interlock feature 106, e.g. through the interlock feature 106, and to monitor an electrical parameter associated with the interlock feature 106. For example, the control unit 114 may be configured to monitor a voltage, current, resistance, and/or capacitance of the interlock feature 106. The control unit 114 may be configured, for example, to determine whether the electrical parameter has fallen outside of a pre-determined range, which may indicate that the interlock feature 106 has become damaged and/or disconnected from the housing 110, and therefore that the integrity of one or more components of the optical module 100 has become compromised. Alternatively, or in addition, the control unit 114 may be configured to detect an interruption in electrical conduction through the interlock feature 106. The control unit 114 may be further configured to transmit an alert to a user to inform the user that the optoelectronic module 100 may be unsafe. Alternatively, or in addition, the control unit 114 may be coupled to the radiation-emitting device 112, and the control unit 114 may be configured to transmit a control signal to the radiation-emitting device 112. The control signal may, for example, direct the radiation-emitting device 112 to turn off or otherwise regulate (e.g. reduce) its optical power output to a safe level. The interlock feature 106 therefore serves to prevent accidental harm to a person that may otherwise be caused by direct exposure to high power radiation emission.

FIGS. 3a-d illustrate plan views of example optoelectronic modules 100 comprising an interlock feature 106 coupled to two terminals 104a, 104b. FIGS. 3a and 3b illustrate an example where the housing 110 of the optoelectronic module 100 has a cuboidal shape, providing a square upper surface 102 of the walls 109, while FIGS. 3c and 3d illustrate an example where the housing 110 is cylindrically shaped, providing a circular upper surface 102 of the wall 109.

The optoelectronic module 100 is operable to illuminate an object or a scene such that the optical module provides a field of illumination (FoI) 130 having a particular shape. The FoI 130 may be affected by its orientation. For example, the FoI 130 may be rectangular with an aspect ratio other than 1:1. However, other shapes of the FoI 130, e.g. elliptical, are possible. The rectangular FoI 130 may be configured to match a shape and orientation of a field of view (FoV) of a camera, e.g. portrait or landscape.

The FoI 130 may be determined by the optical properties of the transparent substrate 106. In some embodiments, the optoelectronic module 100 may further comprise an optical element 105 coupled to the transparent substrate 106, as illustrated in FIGS. 1a-c. The optical element 105 may comprise, for example, one or more lenses, a microlens array, and/or a diffuser. In embodiments comprising an optical element 105, the FoI 130 may be determined by the optical element 105, alone or in combination with the transparent substrate 106.

In the examples illustrated in FIGS. 3a-d, two terminals 104a, 104b are disposed on the surface 102 of the wall or walls 109, and the interlock feature 106. In FIG. 3a, the transparent substrate 116 is arranged in a first orientation about an optical axis 118 of the radiation-emitting device 112, such that a first terminal 104a is coupled to a first point on the interlock feature 106 and a second terminal 104b is coupled to a second point of the interlock feature 106. In the examples illustrated herein, the first and second points of the interlock feature 106 are the ends of a looping path. However, the interlock feature 106 may have any shape and the terminals 104a, 104b may couple to the interlock feature 106 at any suitable point on that shape. The interlock feature 106 comprises contact pads at the points of coupling to the terminals 104a, 104b to facilitate the formation of an electrical contact between the interlock feature 106 and the terminals 104a, 104b. It will be appreciated that the term “contact pad” may simply describe a point at which the interlock feature 106 abuts a terminal 104a, 104b. When the transparent substrate 116 is in the first orientation, the optoelectronic module 100 is operable to provide a FoI 130 in a first illumination orientation, e.g. portrait, as determined by the transparent substrate 116 and/or the optical element 105 (in embodiments comprising an optical element 105, the orientation of the optical element 105 is equivalent to the orientation of the transparent substrate 116, since the optical element 105 is coupled to the transparent substrate 116).

FIG. 3b illustrates an optoelectronic module 100 corresponding to the optoelectronic module 100 of FIG. 3a, differing only in that the transparent substrate 116 is arranged in a second orientation about the optical axis 118 of the radiation-emitting device 112. Due to the arrangement of the terminals 104a, 104b on the surface 102, and the shape of the interlock feature 106, the interlock feature 106 is also coupled to the terminals 104a, 104b in the second orientation. When the transparent substrate 116 is in the second orientation, the optoelectronic module 100 is operable to provide a FoI 130 in a second illumination orientation different from the first illumination orientation, e.g. landscape.

Two or more different illumination orientations of the FoI 130 can therefore be provided by a single design of optoelectronic module 100, configurable simply by orientating the transparent substrate 116 as required during the manufacturing process. As an example, a process for manufacturing an optoelectronic module 100 may comprise: forming a plurality of identical optoelectronic modules 100 without the transparent substrate 116; and separately forming a plurality of identical transparent substrates 116 comprising interlock features 106 (and optionally coupled to optical elements 105). In a subsequent step, the transparent substrate 116 is mounted to the surface 102 in a particular orientation, as required. The transparent substrate 116 may be mounted to the surface 102 using a pick-and-place machine. The pick-and-place machine may be configured to determine the orientation of an optoelectronic module 100 by a position and/or orientation of one or more two-dimensional barcodes disposed on or near the optoelectronic module 100 to facilitate placement of the transparent substrate 116 in the desired orientation.

FIGS. 3a and 3b illustrate an optoelectronic module 100 comprising four walls 109, wherein the first terminal 104a is disposed on a surface of a first wall, and the second terminal 104b is disposed on a surface of the remaining three walls. However, it will be appreciated that any arrangement of terminals 104a, 104b may be employed. For example, in the example illustrated in FIGS. 3c and 3d, the optoelectronic module 100 comprises a single, cylindrical wall, 109, in which the first terminal 104a is disposed on a surface of a first portion of the wall 109, and the second terminal 104b is disposed on a surface of a second portion of the wall 109. Other arrangements are possible with any number of terminals 104 arranged in any suitable formation.

The interlock feature 106 employed in the examples described above, and illustrated in FIGS. 3a-d, is coupled to two terminals 104a, 104b. In the illustrated examples, a first contact pad of the interlock feature 106 is coupled to the first terminal 104a and a second contact pad of the interlock feature 106 is coupled to the second terminal 104b in the first orientation, while in the second orientation the first contact pad of the interlock feature 106 is coupled to the second terminal 104b and the second contact pad of the interlock feature 106 is coupled to the first terminal 104a. However, it will be appreciated that arrangements comprising more than two terminals 104, for example three or four terminals 104 in total, are possible for an interlock feature 106 that comprises two points (e.g. two contact pads) for coupling to terminals 104. Arrangements comprising more than two terminals 104 may employ redundant terminals, wherein the terminals 104 to which the interlock feature 106 is coupled are determined by the orientation of the transparent substrate 116. For example, an optoelectronic module 100 may comprise first, second, third, and fourth terminals disposed on the surface 102. The first and second terminals may both be connected to the control unit 114 to provide current in, and the third and fourth terminals may both be connected to the control unit 114 to provide current out. When the transparent substrate 116 is in the first orientation, the interlock feature 106 may be coupled to the first and third terminals. When the transparent substrate 116 is in the second orientation, the interlock feature may be coupled to the second and fourth terminals.

The examples described thus far enable two-point probe monitoring of the electrical parameter associated with the interlock feature 106. However, it may be desirable that the optoelectronic module 100 be configured to perform four-point probe monitoring of the electrical parameter. In a four-point probe measurement, electrical current is supplied to the interlock feature 106 via a first pair of terminals, and the electrical parameter associated with the interlock feature 106 is measured via a second pair of terminals. The impact of contact resistance between the interlock feature 106 and the terminals 104 is thereby eliminated from the measurement. This can lead to improved uniformity of performance between individual optoelectronic modules 100. Furthermore, the electrical parameter can be measured with improved accuracy in cases where the resistance of the interlock feature 106 is comparable to the contact resistance, such as where the path of the electrical current through the interlock feature 106 is very short (i.e. in very small optoelectronic modules 100).

An example of an embodiment of the optoelectronic module 100 configured for four-point probe monitoring is illustrated in FIG. 4. The optoelectronic module 100 comprises a first terminal 104a, a second terminal 104b, a third terminal 104c, and a fourth terminal 104d disposed on the surface 102. FIG. 5 illustrates a circuit diagram detailing an example configuration of the four terminals 104a, 104b, 104c, 104d. In the example illustrated in FIGS. 4 and 5, the first terminal 104a is configured for current input and the fourth terminal 104d is configured for current output, and the electrical parameter (voltage in the example of FIG. 5) is measured between the second terminal 104b and the third terminal 104c. In the example illustrated in FIG. 4, the transparent substrate 116 is in a first orientation, and the FoI 130 is in a first illumination orientation (portrait). A first contact pad of the interlock feature 106 is coupled to the first terminal 104a, a second contact pad of the interlock feature 106 is coupled to the second terminal 104b, a third contact pad of the interlock feature 106 is coupled to the third terminal 104c, and a fourth contact pad of the interlock feature 106 is coupled to the fourth terminal 104d. It will be appreciated that, following a rotation of the transparent substrate 116 in FIG. 4 by 90 degrees, the transparent substrate 116 would be in a second orientation and the FoI 130 would be in a second illumination orientation (landscape). In the second orientation, the first contact pad of the interlock feature 106 is coupled to the second terminal 104b, the second contact pad of the interlock feature 106 is coupled to the third terminal 104c, the third contact pad of the interlock feature 106 is coupled to the fourth terminal 104d, and the fourth contact pad of the interlock feature 106 is coupled to the first terminal 104a. Four-point probe monitoring of the electrical parameter can therefore be achieved in both orientations. It will be appreciated that the arrangement of the terminals 104a, 104b, 104c, 104d, the shape of the interlock feature 106, the angles of rotation, and the illumination orientations described herein are merely illustrative examples, and that other examples are possible.

In some embodiments, each of the terminals 104a, 104b, 104c, 104d may be reconfigured for current supply and/or electrical parameter monitoring via the control unit 114. For example, in the first orientation the control unit 114 may be configured to supply the electrical current to the interlock feature 106 between the first terminal 104a and the second terminal 104b, and to monitor the electrical parameter between the third terminal 104c and the fourth terminal 104d, while in the second orientation the control unit 114 could be configured to supply the electrical current to the interlock feature 106 between the third terminal 104c and the fourth terminal 104d and to monitor the electrical parameter between the first terminal 104a and the second terminal 104b. Reconfiguring the terminals 104a, 104b, 104c, 104d via the control unit 114 can be advantageous in embodiments where the positions of the contact pads of the interlock feature 106 are optimised for a particular arrangement of the terminals 104a, 104b, 104c, 104d (i.e. current supply and electrical parameter monitoring), as the same contact pads can be optimally coupled for current supply and electrical parameter monitoring in both orientations.

The example interlock feature 106 illustrated in FIG. 4 may, in some embodiments, form part of a Wheatstone bridge configuration for monitoring the electrical parameter. For example, the control unit 114 can be further configured to provide a variable resistance and two known resistances, and to determine a resistance of the interlock feature 106 by adjusting the variable resistance until no voltage is detected between the terminals that are configured for monitoring the electrical parameter. By configuring the terminals 104a, 104b, 104c, 104d, the interlock feature 106, and the control unit 114 as a Wheatstone bridge, the electrical parameter can be determined to a very high precision.

FIGS. 6a and 6b illustrate a further example of an optoelectronic module 100 configured for four-point probe measurements of the electrical parameter. The optoelectronic module 100 illustrated in FIGS. 6a and 6b comprises a first terminal 104a, a second terminal 104b, a third terminal 104c, a fourth terminal 104d, a fifth terminal 104e, and a sixth terminal 104f. FIG. 6a illustrates a transparent substrate 116 comprising an interlock feature 106 in a first orientation, wherein the FoI 130 is in a first illumination orientation (e.g. portrait). The interlock feature 106 comprises four contact points (contact pads) for coupling to the terminals 104a, 104b, 104c, 104d, 104e, 104f. In the first orientation, a first contact pad of the interlock feature 106 is coupled to the second terminal 104b, a second contact pad of the interlock feature 106 is coupled to the third terminal 104c, a third contact pad of the interlock feature 106 is coupled to the fourth terminal 104d, and a fourth contact pad of the interlock feature 106 is coupled to the fifth terminal 106e. In the first orientation, the interlock feature 106 is not coupled to the first terminal 104a or the sixth terminal 104f. FIG. 6b illustrates the transparent substrate 116 in a second orientation, wherein the FoI 130 is in a second illumination orientation (e.g. landscape). In the second orientation, the first contact pad of the interlock feature 106 is coupled to the fourth terminal 104d, the second contact pad of the interlock feature 106 is coupled to the fifth terminal 104e, the third contact pad of the interlock feature 106 is coupled to the sixth terminal 104f, and the fourth contact pad of the interlock feature 106 is coupled to the first terminal 104a. In the second orientation, the interlock feature 106 is not coupled to the second terminal 104b or the third terminal 104c.

FIG. 7 illustrates a circuit diagram detailing an example configuration of the six terminals 104a, 104b, 104c, 104d, 104e, 104f. As illustrated in FIG. 7, the electrical current (“current in”) may be supplied to either the second terminal 104b or the fourth terminal 104d according to a direction of a switch. Likewise, the electrical current may be returned (“current out”) either via the third terminal 104c or via the fifth terminal 104e. The electrical parameter monitoring input (“interlock in”) may be via either the first terminal 104a or via the fifth terminal 104e, and the electrical parameter monitoring output (“interlock out”) may be via either the third terminal 104c or via the sixth terminal 104f. No terminal 104a, 104b, 104c, 104d, 104e, 104f may be configured for more than one function at any time. The terminals 104a, 104b, 104c, 104d, 104e, 104f can therefore be configured using the switches as required according to the orientation. In some examples, the switches may be permanently configured during manufacturing of the optoelectronic module 100 according to the orientation of the transparent substrate 116. In the example illustrated in FIGS. 6a and 6b, the control unit is configured to supply the electrical current to the interlock feature 106 between the second terminal 104b and the third terminal 104c and to monitor the electrical parameter between the fourth terminal 104d and the fifth terminal 104e in the first orientation, and to supply the electrical current to the interlock feature 106 between the fourth terminal 104d and the fifth terminal 104e and to monitor the electrical parameter between the sixth terminal 104f and the first terminal 104a in the second orientation.

In some examples, the interlock feature 106 comprises a long track and a short track. For example, as illustrated in FIGS. 6a and 6b, the path length along the interlock feature 106 between the second terminal 104b and the third terminal 104c in FIG. 6a, and between the fourth terminal 104d and the fifth terminal 104e in FIG. 6b (long track), is considerably longer than the path length between the fourth terminal 104d and the fifth terminal 104e in FIG. 6a, and between the sixth terminal 104f and the first terminal 104a in FIG. 6b (short track). In embodiments configured for four-point probe measurements of the electrical parameter, the current is preferably provided along the long track. The reconfigurable terminals illustrated in FIGS. 4 to 7 are therefore advantageous for four-point probe measurements, as these enable the optoelectronic module 100 to be configured such that the current is provided along the long track in both the first and second orientations.

The optoelectronic module 100 according to the present disclosure may be configured as an infrared illuminator for illuminating an object or a scene. For example, where the optoelectronic module 100 comprises a microlens array and/or a diffuser or other suitable optical element, the optoelectronic module 100 may be configured to illuminate an object or scene with structured illumination, for example to facilitate three-dimensional imaging. Alternatively, or in addition, the optoelectronic module may be configured, in combination with a radiation detector configured to detect radiation reflected by the object or scene and having (a) wavelength(s) corresponding to the wavelength(s) of radiation emitted by the radiation-emitting device 112, as a time-of-flight sensor and/or a proximity sensor.

FIG. 8 illustrates a mobile communications device 800 comprising an optoelectronic module 100 according to any of the embodiments described herein. The mobile communications device 800 may be, for example, a smartphone, a tablet device, a laptop computer, or a camera. In the example illustrated in FIG. 8, the optoelectronic module 100 is shown as being incorporated into the mobile communications device behind a display 810. The display 810 may be, for example, an LED display, such as an organic LED display. However, an optoelectronic module 100 according to the present disclosure may be alternatively or additionally incorporated into a bezel 850 of the mobile communications device 800.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### LIST OF REFERENCE NUMERALS

100 optoelectronic module
102 surface of wall or walls
104a first terminal
104b second terminal
104c third terminal
104d fourth terminal
104e fifth terminal
104f sixth terminal
105 optical element
106 interlock feature
108 base
109 wall
110 housing
112 radiation-emitting device
114 control unit
115 protective layer
116 transparent substrate
118 optical axis
800 mobile communications device
810 screen
850 bezel

1. An optoelectronic module comprising:
a radiation-emitting device;
a housing comprising a wall or walls laterally surrounding the radiation-emitting device;
two or more terminals disposed on a surface of the wall or walls;
a transparent substrate abutting the housing, the transparent substrate comprising an interlock feature;
a control unit coupled to the two or more terminals, wherein the control unit is configured to:
supply an electrical current though the interlock feature;
monitor an electrical parameter associated with the interlock feature;
wherein the terminals are arranged such that:
when the transparent substrate is in a first orientation about an optical axis of the radiation-emitting device, the interlock feature is coupled to at least two of the two or more terminals and the optoelectronic module is operable to provide a field of illumination in a first illumination orientation; and
when the transparent substrate is in a second orientation about the optical axis of the radiation-emitting device, the interlock feature is coupled to at least two of the two or more terminals and the optoelectronic module is operable to provide a field of illumination in a second illumination orientation different from the first illumination orientation.

2. The optoelectronic module of claim 1, wherein the two or more terminals comprise a first terminal and a second terminal, wherein in the first orientation a first contact pad of the interlock feature is coupled to the first terminal and a second contact pad of the interlock feature is coupled to the second terminal; and
wherein in the second orientation the first contact pad of the interlock feature is coupled to the second terminal and the second contact pad of the interlock feature is coupled to the first terminal.

3. The optoelectronic module of claim 2, comprising a plurality of walls, wherein the first terminal is disposed on a surface of a first wall of the housing, and wherein the second terminal is disposed on a surface of one or more further walls of the housing.

4. The optoelectronic module of claim 2, comprising one wall, wherein the first terminal is disposed on a first portion of the surface of the wall, and wherein the second terminal is disposed on a second portion of the surface of the wall.

5. The optoelectronic module of claim 1, wherein the two or more terminals comprise a first terminal, a second terminal, a third terminal, and a fourth terminal, wherein in the first orientation a first contact pad of the interlock feature is coupled to the first terminal, a second contact pad of the interlock feature is coupled to the second terminal, a third contact pad of the interlock feature is coupled to the third terminal, and a fourth contact pad of the interlock feature is coupled to the fourth terminal; and
wherein in the second orientation the first contact pad of the interlock feature is coupled to the second terminal, the second contact pad of the interlock feature is coupled to the third terminal, the third contact pad of the interlock feature is coupled to the fourth terminal, and the fourth contact pad of the interlock feature is coupled to the first terminal.

6. The optoelectronic module of claim 5, wherein in the first orientation the control unit is configured to supply the electrical current to the interlock feature between the first terminal and the second terminal and to monitor the electrical parameter between the third terminal and the fourth terminal; and
wherein in the second orientation the control unit is configured to supply the electrical current to the interlock feature between the third terminal and the fourth terminal and to monitor the electrical parameter between the first terminal and the second terminal.

7. The optoelectronic module of claim 5, wherein the terminals, the interlock feature, and the control unit are configured as a Wheatstone bridge.

8. The optoelectronic module of claim 1, wherein the two or more terminals comprise a first terminal, a second terminal, a third terminal, a fourth terminal, a fifth terminal, and a sixth terminal, wherein in the first orientation a first contact pad of the interlock feature is coupled to the second terminal, a second contact pad of the interlock feature is coupled to the third terminal, a third contact pad of the interlock feature is coupled to the fourth terminal, and a fourth contact pad of the interlock feature is coupled to the fifth terminal; and
wherein in the second orientation the first contact pad of the interlock feature is coupled to the fourth terminal, the second contact pad of the interlock feature is coupled to the fifth terminal, the third contact pad of the interlock feature is coupled to the sixth terminal, and the fourth contact pad of the interlock feature is coupled to the first terminal; and
wherein in the first orientation the control unit is configured to supply the electrical current to the interlock feature between the second terminal and the third terminal and to monitor the electrical parameter between the fourth terminal and the fifth terminal; and
wherein in the second orientation the control unit is configured to supply the electrical current to the interlock feature between the fourth terminal and the fifth terminal and to monitor the electrical parameter between the sixth terminal and the first terminal.

9. The optoelectronic module of claim 5, wherein the interlock feature comprises a first track and a second track, wherein the first track is longer than the second track and the electrical current is provided along the first track.

10. The optoelectronic module of claim 1, further comprising an optical element coupled to the transparent substrate, wherein the optical element is configured to provide the field of illumination.

11. The optoelectronic module of claim 1, wherein the electrical parameter comprises one or more of:
a voltage;
a current;
a capacitance; and/or
a resistance.

12. The optoelectronic module of claim 1, wherein the radiation-emitting device comprises at least one vertical-cavity surface-emitting laser.

13. The optoelectronic module of claim 1, wherein the control unit is further configured to initiate a safety action if the electrical parameter falls outside of a pre-determined acceptable range, wherein initiating the safety action comprises transmitting a control signal to the radiation-emitting device.

14. The optoelectronic module of claim 1, wherein the interlock feature is disposed on a surface of the transparent substrate.

15. The optoelectronic module of claim 1, wherein the transparent substrate is made of glass.

16. The optoelectronic module of claim 1, wherein the terminals are disposed on an upper surface of the wall or walls.

17. The optoelectronic module of claim 1, wherein the terminals are disposed on a side surface of the wall or walls.

18. The optoelectronic module of claim 1, wherein the optoelectronic module is configured as one or more of:
an infrared illuminator;
a time-of-flight sensor; and/or
a proximity sensor.

19. A mobile communications device comprising the optoelectronic module of claim 1.
